(19) United States
(12) Patent Application Publication
(10) Pub. No.: US 2024/0420958 A1
(43) Pub. Date: Dec. 19, 2024

(54) METHOD, SYSTEM, AND APPARATUS FOR DEPOSITION OF TRANSITION METAL FILM

(71) Applicant: ASM IP Holding B.V., Almere (NL)

(72) Inventors: Venkata Surya Naga Raju Chava, Tempe, AZ (US); Estiaque Haidar Shourov, Mesa, AZ (US); Robert Brennan Milligan, Phoenix, AZ (US); Mojtaba Samiee, Tempe, AZ (US); Balaji Kannan, Phoenix, AZ (US); Dong Li, Phoenix, AZ (US); Rajkumar Jakkaraju, Phoenix, AZ (US)

(21) Appl. No.: 18/740,699

(22) Filed: Jun. 12, 2024

Related U.S. Application Data
(60) Provisional application No. 63/521,618, filed on Jun. 16, 2023.

(51) Int. Cl. H01L 21/28; C23C 16/34; C23C 16/40; C23C 16/455; C23C 16/50; H01J 37/32; H01L 21/02

(52) U.S. Cl. CPC H01L 21/28088; C23C 16/34; C23C 16/403; C23C 16/405; C23C 16/45536; C23C 16/50; H01J 37/32357; H01L 21/02178; H01L 21/02181; H01L 21/02192; H01J 2237/332

(57) ABSTRACT

Methods, system and apparatus for semiconductor processing including supporting a substrate comprising one or more oxide layers disposed on the substrate on a substrate support in a first reaction chamber, contacting a top surface of the one or more oxide layers of the substrate with an excited species, supporting the substrate in a second reaction chamber and depositing a transition metal layer over the top surface subsequent to contacting the top surface with the excited species.

### CROSS-REFERENCE TO RELATED APPLICATIONS

This application is a nonprovisional of, and claims priority to and the benefit of, U.S. Provisional Patent Application No. 63/521,618, filed Jun. 16, 2023 and entitled “METHOD, SYSTEM, AND APPARATUS FOR DEPOSITION OF TRANSITION METAL FILM,” which is hereby incorporated by reference herein.

### FIELD OF THE DISCLOSURE

This disclosure relates to the field of semiconductor processing and, more particularly, to the deposition of conductive structures, such as metal gate electrodes, including metal gate electrodes in gate stacks in transistors.

### BACKGROUND OF THE DISCLOSURE

The scaling of semiconductor devices, such as, complementary metal-oxide-semiconductor (CMOS) devices, has led to significant improvements in speed and density of integrated circuits. However, conventional device scaling techniques face significant challenges for future technology nodes.

A perennial issue in aggressively scaled semiconductor devices is a decrease in throughput due to ever increasing complexity of processing at advanced technology nodes. Nucleation delay is a major contributor to reduced throughput. Therefore, methods, systems, apparatus, and materials to reduce nucleation delay are desired.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Disclosed herein are examples of a semiconductor processing method, system and apparatus for supporting a substrate comprising one or more oxide layers disposed on the substrate on a substrate support in a first reaction chamber, contacting a top surface of the one or more oxide layers of the substrate with an excited species, supporting the substrate in a second reaction chamber and depositing a transition metal layer over the top surface subsequent to contacting the top surface with the excited species. In some examples, the semiconductor processing method, system and apparatus further comprises depositing the one or more oxide layers on a surface of the substrate. The semiconductor processing method, system and apparatus may include wherein the depositing the transition metal layer comprises exposing the substrate to one or more transition metal layer precursors, wherein the transition metal layer is a transition metal nitride, and/or wherein the transition metal nitride is molybdenum nitride (MoN) or tungsten nitride (WN).

In some examples, the semiconductor processing method, system and apparatus further comprise wherein the one or more transition metal layer precursors are selected from the group comprising: bis(tert-butylimino) bis(tert-butoxy) Mo, bis(tert-butylimido)bis(dimethylamido) Mo, bis(tert-butylimido)bis(dimethylamido) Mo, molybdenum hexacarbonyl, molybdenum pentachloride, Mo(NtBu)₂(StBu)₂, Mo(NMe₂)₄, Mo(NEt₂)₄, Mo₂(NMe₂)₆, Mo(tBuN)₂(NMe₂)₂, Mo(tBuN)₂(NEt₂)₂, Mo(NEtMe)₄, Mo(NtBu)₂(StBu)₂, Mo(NtBu)₂(iPr₂AMD)₂Mo(thd)₃, MoO₂(acac), MoO₂(thd)₂, MoO₂(iPr₂AMD)₂, bis(tert-butylimido)-bis-(dimethylamido)tungsten, bis(tertbutylimido)-bis(tert-butylamido)tungsten, or a combination thereof.

In some examples, the semiconductor processing method, system and apparatus includes wherein the depositing the one or more oxide layers on the top surface of the substrate comprises contacting the substrate with a first precursor to deposit a first oxide layer comprising a first metal oxide and contacting the substrate with a second precursor to deposit a second oxide layer comprising a second metal oxide.

In some examples, the semiconductor processing method, system and apparatus further includes wherein the first metal oxide is different from the second metal oxide, wherein the first metal oxide is deposited directly on a surface of the substrate to form a first metal oxide layer and the second metal oxide is deposited directly on a top surface of the first metal oxide layer to form a second metal oxide layer, wherein the first metal oxide layer is thicker than the second metal oxide layer, and/or wherein the first metal oxide layer is about 15 angstroms thick and the second metal oxide layer is about 10 angstroms thick.

In some examples, the semiconductor processing method, system and apparatus may include wherein the first metal oxide layer comprises hafnium oxide (HfO₂) and the second metal oxide layer comprises lanthanum oxide (La₂O₃) or aluminum oxide (Al₂O₃), or a combination thereof.

In some examples, the semiconductor processing method, system and apparatus may include wherein the excited species is generated in a remote plasma unit (RPU), wherein the excited species are radicals of argon (Ar), hydrogen (H₂), or nitrogen (N₂), or a combination thereof, and/or wherein H₂ and N₂ are combined in a predetermined ratio.

In some examples, the semiconductor processing method, system and apparatus may include wherein the excited species is H₂.

In some examples, the semiconductor processing method, system and apparatus may include wherein contacting the top surface of the one or more oxide layers of the substrate further comprises heating the substrate support to adjust a temperature of the substrate and/or wherein the substrate support is heated to about 360° C.

In some examples, the semiconductor processing method, system and apparatus may include wherein the depositing the one or more oxide layers on the substrate and the contacting the top surface of the one or more oxide layers of the substrate with an excited species are performed in a same reaction chamber.

In some examples, the semiconductor processing method, system and apparatus may include wherein the depositing the one or more oxide layers on the substrate, the contacting the top surface of the one or more oxide layers of the substrate with an excited species and the depositing the transition metal layer over the substrate surface are performed in a same reaction chamber.

In some examples, the semiconductor processing method, system and apparatus may include wherein the depositing the one or more oxide layers on the substrate, the contacting the top surface of the one or more oxide layers of the substrate with an excited species and the depositing the transition metal layer over the substrate surface are performed in two or more reaction chambers and/or wherein the first reaction chamber and the second reaction chamber are the same chamber.

All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as embodiments or examples of the disclosure, the advantages of examples of the disclosure may be more readily ascertained from the description of certain examples of the disclosure when read in conjunction with the accompanying drawings.

Elements with the like element numbering throughout the figures are intended to be the same.

FIG. 1A illustrates a schematic diagram of a reactor system, in accordance with an example of the present technology.

FIG. 1B illustrates a schematic diagram of a reactor system, in accordance with an example of the present technology.

FIG. 1C illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates a device structure, in accordance with an example of the present technology.

FIG. 4 illustrates a material processing method, in accordance with an example of the present technology.

FIG. 5 illustrates a device structure, in accordance with an example of the present technology.

FIG. 6 illustrates a material processing method, in accordance with an example of the present technology.

### DETAILED DESCRIPTION

Although certain embodiments and examples are disclosed below, it will be understood by those in the art that the invention extends beyond the specifically disclosed embodiments and/or uses of the disclosed technology and obvious modifications and equivalents thereof. Thus, it is intended that the scope of the invention disclosed should not be limited by the particular disclosed embodiments described below. It is to be understood that not necessarily all objects or advantages described herein can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

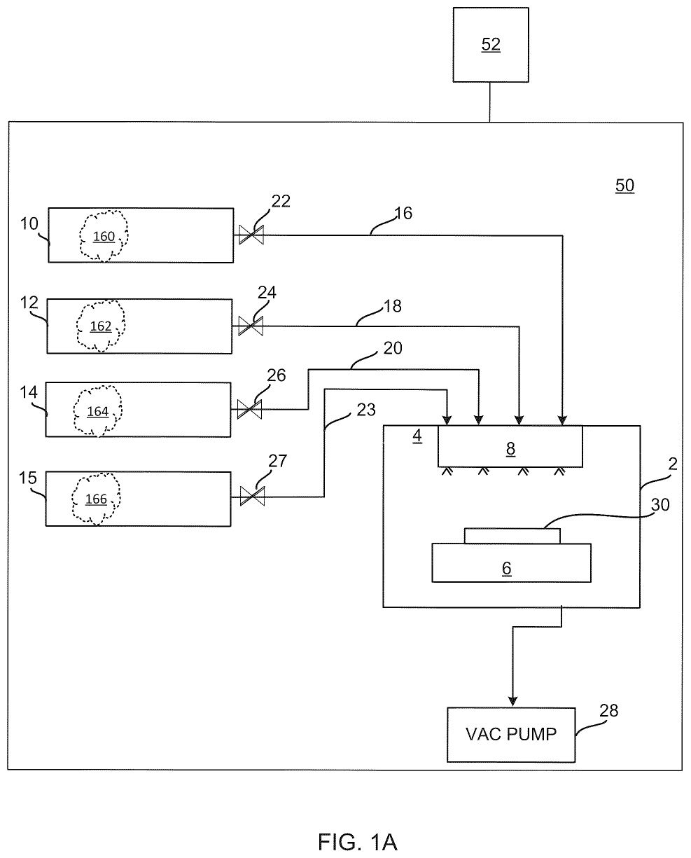

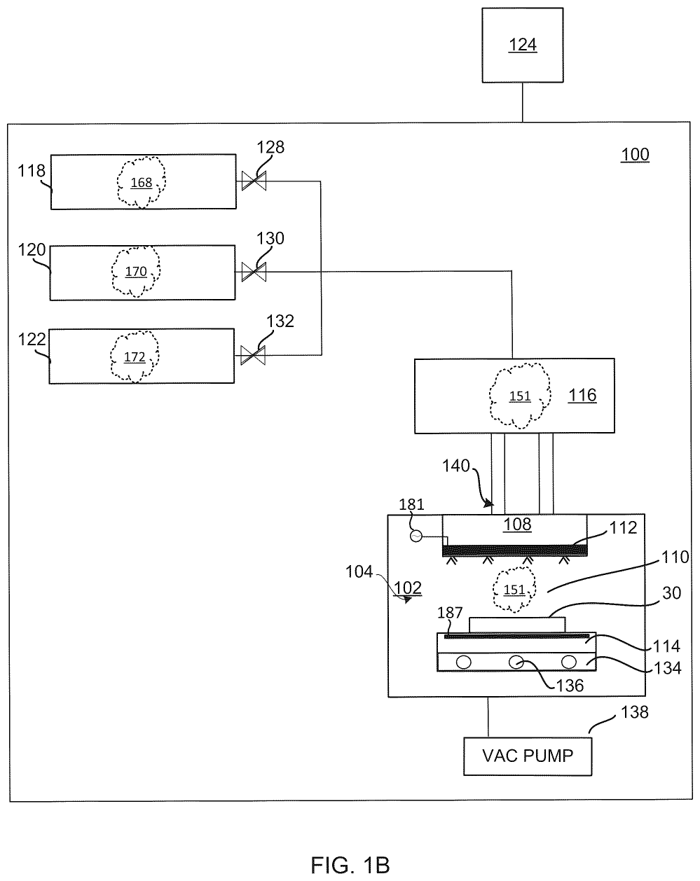

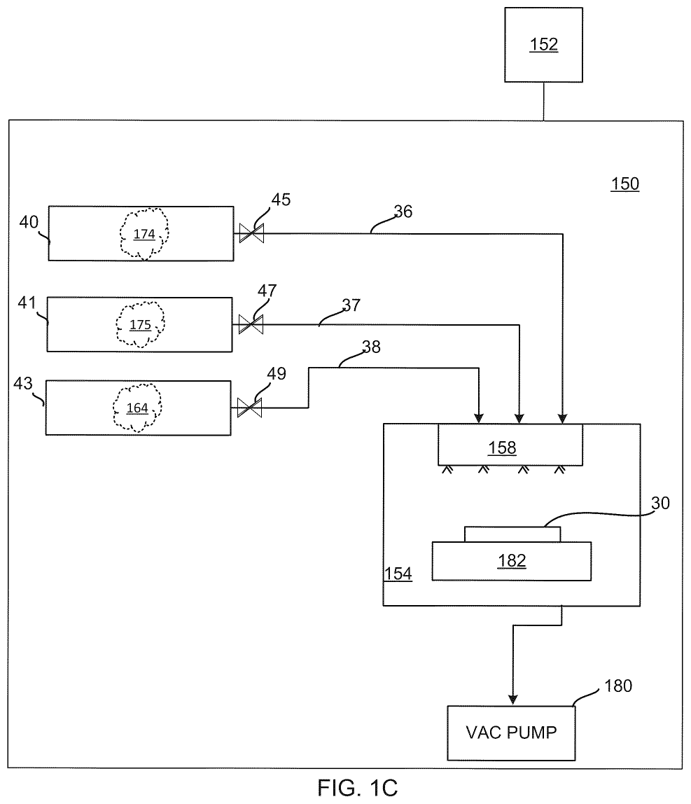

FIG. 1A illustrates a schematic diagram of a reactor system 50, in accordance with examples of the present technology. Reactor systems used for ALD, CVD, and/or the like, may be used for a variety of applications, including depositing and etching materials on a substrate surface. In various examples, a reactor system 50 can comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and 15, a carrier and/or purge gas source 14, fluidly coupled to reaction chamber 4 via lines 16-23, and valves or controllers 22-27. Reactant gases or other materials from reactant sources 10, 12 and/or 15 can be applied to substrate 30 in reaction chamber 4. A purge gas 164 from purge gas source 14 can be provided to reaction chamber 4 to remove any excess reactant or other undesired materials from reaction chamber 4. System 50 can also comprise a vacuum pump 28 fluidly coupled to the reaction chamber 4, which can be configured to evacuate reactants, a purge gas 164, or other materials out of reaction chamber 4.

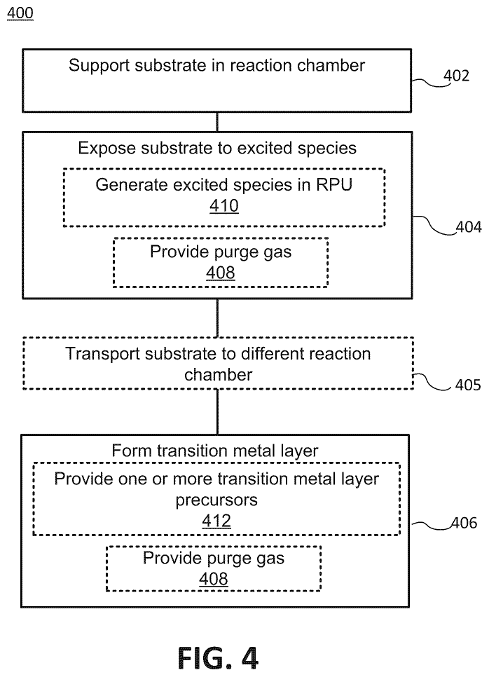

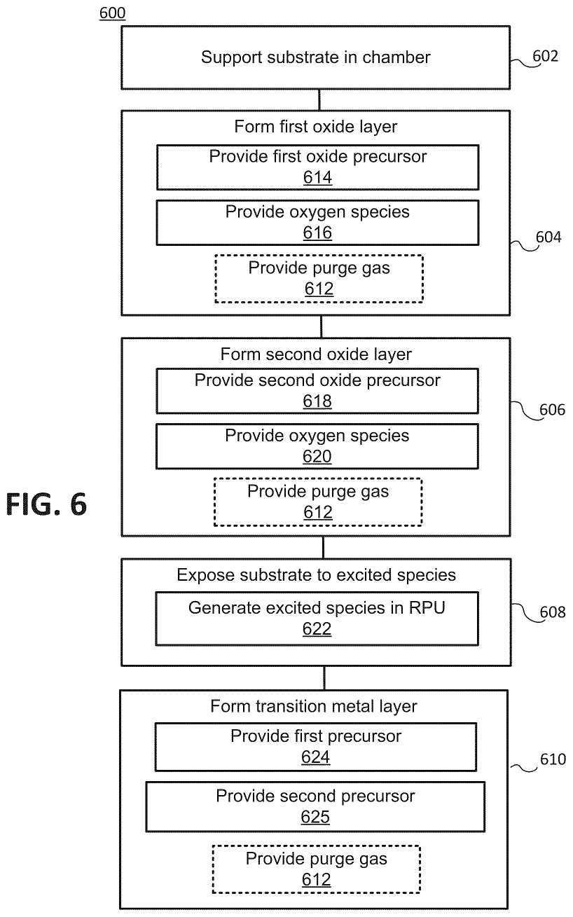

Controller 52 can be configured to perform various functions and/or steps as described herein. Controller 52 can include one or more microprocessors, memory elements, and/or switching elements to perform the various functions. Although illustrated as a single unit, controller 52 can alternatively comprise multiple devices. By way of example, controller 52 can be used to control gas flow (e.g., by monitoring flow rates and controlling valves 22, 24, 26 and/or 27), motors, heaters, cooling devices and/or vacuum pump 28 to execute various processes (e.g., method 400 in FIG. 4 and/or method 600 in FIG. 6). Further, when a system includes two or more reaction chambers, as described in more detail below, the two or more reaction chambers can be coupled to the same/shared controller.

FIG. 1B illustrates a reactor system 100 in accordance with exemplary embodiments of the disclosure. Reactor system 100 includes a reaction chamber 102, including a gas distribution assembly 108, showerhead plate 112 and a gas expansion area 110; a substrate support 114; a remote plasma unit (RPU) 116; a first gas source 118; a second gas source 120; a third gas source 122; vacuum pump 138 and a controller 124.

In an example, reactor system 100 can provide excited species 151 (e.g., radicals of hydrogen, nitrogen, or argon, or the like or combinations thereof) to gas distribution assembly 108, reaction chamber 102 and/or substrate 30 within reaction chamber 102.

In an example, RPU 116 may be coupled to respective chemical sources 118 and/or 120 supplying respective vapor phase reactants 168 and/or 170 via respective chemical delivery lines. The vapor phase reactants may be activated by RPU 116 to generate an excited species 151

For simplicity, the term “excited species” used herein can be understood to encompass electrons, ions, radicals, atoms or other excited species that can, for example, be generated by a plasma. Typically, the excited species 151 are formed in a plasma discharge and depending on how they are supplied to the reaction space 110, where substrate (e.g., substrate 30) is supported. In an example, excited species 151 may comprise electrons, ions, radicals and/or atoms, for example oxygen, hydrogen, nitrogen, argon or nitrogen plasma, atomic oxygen/hydrogen/nitrogen, radicals of hydrogen, argon, nitrogen, fluorine, oxygen, nitrogen trifluoride, chlorine, or the like, or a combination thereof. Such excited species may be used in one or more substrate surface treatment operations. Other radical species may be used and claimed subject matter is not limited in this regard. In various embodiments excited species may be generated by coupling power, such as by radio frequency (RF) alternated electrical fields, microwave standing waves, ultraviolet light, or other forms of energy, to the flowing vapor phase reactant that may be supplied to RPU 116.

In an example, substrate support 114 (also referred to herein as “susceptor”) may be operable to support substrate 30 within chamber 102. Susceptor 114 can include one or more heaters 134 and/or one or more cooling devices 136 (e.g., conduits for cooling fluid). Gas distribution assembly 108 is coupled to RPU 116 and receives activated species from RPU 116, distributes the activated species via transport path 140 to gas expansion area 110 and provides the activated species to a surface of a substrate 30 via showerhead plate 112. As discussed in more detail below, gas distribution assembly 108, gas expansion area 110, and showerhead plate 112 can be used to distribute the excited species 151 in a desired manner to provide, for example, a desired amount, flowrate, or flux of excited species 151 to areas on a substrate 30 surface.

Gas source 118 can include any suitable gas, such as an inert gas. By way of examples, gas source 118 can include one or more of argon, helium, or neon. Gas source 120 can include any suitable gas. By way of examples, gas source 120 can include one or more of nitrogen, oxygen, or water vapor. Gas source 122 may contain any suitable gas, such as an active gas. By way of examples, gas source 122 can include one or more of hydrogen, nitrogen or ammonia.

Controller 124 can be configured to perform various functions and/or steps as described herein. Controller 124 can include one or more microprocessors, memory elements, and/or switching elements to perform various functions. Although illustrated as a single unit, controller 124 can alternatively comprise multiple devices. By way of example, controller 124 can be used to control gas flow (e.g., by monitoring flow rates and controlling valves 128, 130, and/or 132), motors, heaters, cooling devices (e.g., heater 134 and/or cooling device 136) to execute various processes (e.g., method 400 in FIG. 4 and/or method 600 in FIG. 6). Further, when a system includes two or more reaction chambers, as described in more detail below, the two or more reaction chambers can be coupled to the same/shared controller (such as controller 52 or controller 124).

FIG. 1C illustrates a schematic diagram of a reactor system 150, in accordance with examples of the present technology. Reactor system 150 can comprise a reaction chamber 154, a susceptor 182 to hold a substrate during processing, a fluid distribution system 158 (e.g., a showerhead) to distribute one or more reactants to a surface of substrate 30, one or more reactant sources 40, 41, 44 and/or a carrier and/or purge gas source 43, fluidly coupled to reaction chamber 154 via lines 36-39 and respective valves or controllers 45, 47, 49, and 53. Reactant gases or other materials from reactant sources 40, 41, 44 can be applied to substrate 30 in reaction chamber 154. A purge gas 164 from purge gas source 43 may be flowed to and through reaction chamber 154 to remove any excess reactant or other undesired materials from reaction chamber 154. System 150 can also comprise a vacuum pump 180 fluidly coupled to the reaction chamber 154, which can be configured to evacuate reactants, a purge gas 164, or other materials out of reaction chamber 154.

Controller 152 can be configured to perform various functions and/or steps as described herein. Controller 152 can include one or more microprocessors, memory elements, and/or switching elements to perform the various functions. Although illustrated as a single unit, controller 152 can alternatively comprise multiple devices. By way of examples, controller 152 can be used to control gas flow (e.g., by monitoring flow rates and controlling valves 45, 47, 49), motors, heaters, cooling devices and/or vacuum pump 180 to execute various processes (e.g., method 400 in FIG. 4 and/or method 600 in FIG. 6). Further, when a system includes two or more reaction chambers, as described in more detail below, the two or more reaction chambers can be coupled to the same/shared controller.

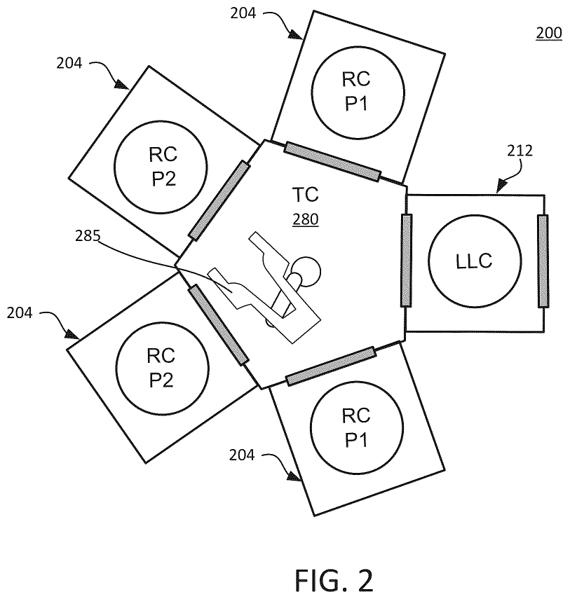

In various examples, a reactor system 50, reactor system 100 and/or reactor system 150 can comprise multiple reaction chambers. For example, in reactor system 200, shown in FIG. 2, a number of reaction chambers 204 (each of which can be an example of reaction chamber 4, reaction chamber 102 or reaction chamber 154) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 30 can be disposed in different chambers for different steps in a deposition process.

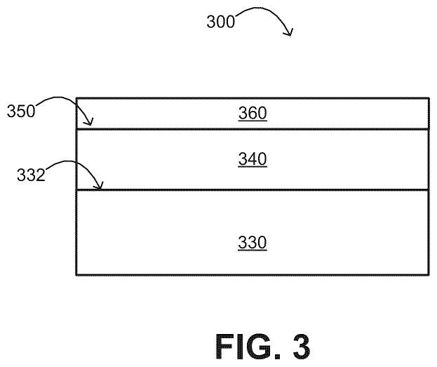

FIG. 4 depicts a method 400 of treating a surface of a substrate to form a device structure, such as device structure 300 illustrated in FIG. 3. Device structure 300 may be an intermediate structure formed during fabrication of gate electrode structures suitable for NMOS, PMOS, and/or CMOS devices, such as for use as a dipole layer in a gate, source, or drain electrode of a metal oxide semiconductor. However, unless otherwise noted, the presently described methods are not limited to such applications.

With combined reference to FIGS. 1A-1C and FIGS. 3-4, method 400 may begin with step 402 wherein a substrate 330 may be supported in a reaction chamber (e.g., reaction chamber 102 in FIG. 1B). Substrate 330 can be disposed on a susceptor (e.g., susceptor 114 in FIG. 1B) for processing. In an example, at the beginning of method 400, substrate 330 may comprise layer 340 disposed on top surface 332 of substrate 330. Layer 340 may comprise one or more oxide layers. In some examples the oxide layer 340 comprises one or more metal oxides.

At step 404, substrate 330 may be exposed to an excited species 151 to treat a surface 350 of layer 340 in reaction chamber 102. In an example, the excited species 151 may be generated in an RPU 116 (step 410) and transported to reaction chamber 102 via transport path 140. Alternatively, excited species 151 may be generated within reaction chamber 102 wherein the plasma source is a direct plasma source and chamber 102 includes one or more electrodes 181, 187 and an RF power source configured to generate plasma within the reaction space 110.

In an example, excited species 151 may contact substrate 330 surface 350 within reaction chamber 102. Excited species may comprise hydrogen (H₂), nitrogen (N₂), ammonia (NH₃) and/or a noble gas (e.g., argon (Ar) and/or helium (He)) or the like or combinations thereof. H₂, N₂, NH₃ and/or the noble gas may be excited in RPU 116 alone or in a ratio. In an example, an H₂/N₂ ratio may be in the range of about 0 to 2, or about 0.25 or in the range of about 2 to 5, or about 4. Other ranges are possible and claimed subject matter is not limited in this regard.

In an example, RPU 116 may generate active species over a variety of time periods, such as, over a range of about 1-500 seconds. Other ranges are possible and claimed subject matter is not limited in this regard.

During exposure to the excited species, substrate 330 may be heated. In an example, substrate 330 may be heated by susceptor 114. The temperature of susceptor 114 may be adjusted by heater 134 and/or cooling device 136. In an example, susceptor 114 may be heated to a temperature in the range of 100° C.-300° C., or about 250° C. or in the range of 250° C.-400° C., or about 325° C. or in the range of 300° C.-500° C., or about 400° C. (“about” in this context means plus or minus 50° C.). Other temperatures or temperature ranges are possible and claimed subject matter is not limited in this regard.

In an example, subsequent to exposure to the excited species 151, substrate 330 may optionally be transported to a different reaction chamber (step 405) for additional processing (e.g., reaction chamber 154 see FIG. 1C). Alternatively, substrate 330 may remain within the reaction chamber where the reaction chamber is equipped to perform both material deposition processing and plasma treatment and claimed subject matter is not limited in this regard.

In an example, method 400 may proceed to step 406 where a transition metal layer 360 is formed on plasma treated surface 350. Forming transition metal layer 360 may comprise supporting substrate 330 on a susceptor (e.g., susceptor 182 in FIG. 1C).

At step 412, one or more transition metal layer precursors 174 and 175 may be provided to chamber 154 from respective reactant sources 40 and 41. The one or more transition metal precursors 174 and 175 may be pulsed into reaction chamber 154 in any order, passing through showerhead 158 to substrate 330, or through a crossflow fluid distribution system.

In an example, transition metal layer 360 may comprise a transition metal nitride, such as tungsten nitride (WN), molybdenum nitride (MoN), or the like or a combination thereof.

In various examples, first transition metal precursor 174 may be a transition metal source, for example, a molybdenum or tungsten source.

In an example, first transition metal layer precursor 174 may be a molybdenum (Mo) source and may comprise any suitable Mo containing precursor, such as, for example, a metalorganic precursor, a halide molybdenum precursor, a nitrogen (N)- and/or sulfur(S)-containing molybdenum metalorganic precursor, or the like, or combinations thereof.

In an example, first transition metal layer precursor 174 may comprise, Mo(NtBu)₂(StBu)₂, molybdenum hexacarbonyl (Mo(CO)₆), bis(tert-butylimido)bis(dimethylamido) Mo, bis(tert-butylimino) bis(tert-butoxy) Mo, molybdenum pentachloride (Mo(Cl)₅), Mo(NMe₂)₄, Mo(NEt₂)₄, MO₂(NMe₂)₆, Mo(tBuN)₂(NMe₂)₂, Mo(tBuN)₂(NEt₂)₂, Mo(NEtMe)₄, Mo(NtBu)₂(StBu)₂, Mo(NtBu)₂(iPr₂AMD)₂Mo(thd)₃, MoO₂(acac), MoO₂(thd)₂, and/or MoO₂(iPr₂AMD)₂, or the like or combination thereof.

In another example, first transition metal layer precursor 174 may be a tungsten (W) source and may comprise any suitable W containing precursor such as, for example, bis(tert-butylimido)-bis-(dimethylamido)tungsten ((tBuN)₂(Me₂N)₂W), bis(tertbutylimido)-bis(tert-butylamido)tungsten ((tBuN)₂W—(NHtBu)₂), or the like or combinations thereof.

Second transition metal layer precursor 175 may be a nitrogen source, for example, and may comprise nitrogen (N₂), ammonia (NH₃), hydrazine (N₂H₄), dimethyl hydrazine ((CH₃)₂NNH₂), or the like or combinations thereof.

First transition metal layer precursor 174 and second transition metal layer precursor 175 may comprise other species or compounds known to those of skill in the art and claimed subject matter is not limited in this regard. Moreover, first transition metal layer precursor 174 may serve as both a transition metal source and a source of other constituents of transition metal layer 360.

Precursors 174 and 175 may be pulsed into the reaction chamber 154 for any suitable duration (e.g., for pulse times of between 0.05 to 30 seconds).

At step 408, pulses of transition metal precursor may be separated by providing a purge gas 164 to the reaction chamber 154 to remove excess precursor, byproducts, or other unwanted materials. In various examples, a purge gas 164 can be provided at various intervals and/or between pulses. Purge gas 164 can comprise any suitable gas, such as an inert or nonreactive gas, including helium (He), neon (Ne), argon (Ar), krypton (Kr), xenon (Xe), and/or nitrogen (N₂).

The number of pulses of the one or more precursors 174 and 175 may be determined based on a variety of factors including desired thickness of transition metal layer 360, flow rate, etc. However, nucleation delay of transition metal layer 360 may be reduced on treated surface 350 as compared to a non-treated surface of substrate 330 under the same or similar conditions. Without being bound by theory, treatment of surface 350 by plasma excited species 151 can reduce nucleation delay even after a period of 48 hours from plasma treatment to deposition of transition metal layer 360. Thus, reduction in nucleation delay may not be caused by surface species (e.g., carbon) removal alone.

The pressure within the reaction chamber 154 during provision of the transition metal nitride layer 360 can be any suitable pressure, such as between 0.1 and 10 Torr. The temperature during the steps to form the first transition metal layer 360 can be between 150° C. and 500° C., or about 250° C., or about 350° C., or about 450° C. (“about” in this context means plus or minus 50° C.). Other temperatures or temperature ranges are possible and claimed subject matter is not limited in this regard.

After a desired thickness of transition metal layer 360 is reached, device structure 300 may proceed to further processing. For example, layer 360 may function as an etch stop layer in material processing applications for next-generation transistor architectures and/or fabrication of threshold voltage tuning layers. However, unless otherwise noted, the presently described methods are not limited to such applications.

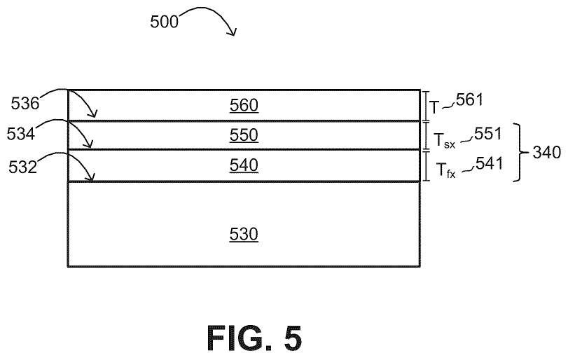

FIG. 6 depicts a method 600 for forming a device structure, such as device structure 500 illustrated in FIG. 5. Device structure 500 may be an intermediate structure formed during fabrication of gate electrode structures suitable for NMOS, PMOS, and/or CMOS devices, such as for use as a dipole layer in a gate, source, or drain electrode of a metal oxide semiconductor. However, unless otherwise noted, the presently described methods are not limited to such applications.

With combined reference to FIGS. 1A-1C, and 5-6, method 600 may begin at step 602 where a substrate 530 may be supported in a reaction chamber (e.g., reaction chamber 4 in FIG. 1A). Substrate 530 can be disposed on a susceptor (e.g., susceptor 6 in FIG. 1A) within reaction chamber 4 for processing.

In an example, method 600 may proceed to step 604 where a first oxide layer 540 may be formed on substrate 530.

In various examples, forming first oxide layer 540 may comprise providing a first oxide precursor 160 (step 614) to a reaction chamber (e.g., reaction chamber 4 in FIG. 1A) where the first oxide precursor 160 may contact top surface 532 of substrate 530. First oxide precursor 160 may be provided to top surface 532 through a showerhead (e.g., showerhead 8), or through a crossflow fluid distribution system. In an example, first oxide layer 540 may comprise a first metal oxide.

In an example, the first oxide layer 540 may comprise hafnium oxide (HfO₂). In various examples, the first oxide precursor 160 may comprise any suitable hafnium compound, such as HfCl₄, tetrakis(diethylamido) hafnium (TDEAH), hafnium isopropoxide (Hf(O-iPr)₄), hafnium tert-butoxide (HTB), tetrakis(ethylmethylamido) hafnium (TEMAH), or tetrakis(dimethylamido) hafnium (TDMAH), or the like or combinations thereof.

The first oxide precursor 160 may be supplied to the chamber via a first reactant source vessel 10. The first oxide precursor 160 can be pulsed into the reaction chamber for any suitable duration (e.g., for pulse times in the range of about 0.05 to 30 seconds). The pressure within the reaction chamber during provision of the first oxide precursor 160 can be any suitable pressure, such as between 0.1 and 10 Torr.

In various examples, forming the first oxide layer may further comprise providing an oxygen species 166 (step 616) to the reaction chamber. The oxygen species can be provided via oxygen source vessel 15 through showerhead 8 to contact top surface 532 of substrate 530, or through a crossflow fluid distribution system. The oxygen species 166 can be pulsed into the reaction chamber for any suitable duration (e.g., for pulse times of between 0.05 to 30 seconds). In various examples, an oxygen species can be continuously provided to reaction chamber 4. The pressure within the reaction chamber during provision of the oxygen species can be any suitable pressure, such as between 0.1 and 10 Torr.

In various examples, oxygen species 166 (step 616) can comprise any suitable compound including oxygen and/or oxidizing compound, such as water (H₂O), ozone (O₃), hydrogen peroxide (H₂O₂), deuterium oxide (D₂O), nitrous oxide (N₂O), nitrogen dioxide (NO₂), and/or an alcohol (e.g., tertbutyl alcohol), or the like or combinations thereof.

The temperature during the steps to form the first oxide layer 540 can be between 150° C. and 400° C., or about 200° C., or about 250° C., or about 300° C., or about 350° C. (“about” in this context means plus or minus 50° C.). Other temperatures or temperature ranges are possible and claimed subject matter is not limited in this regard.

The steps of providing the first oxide precursor 160 (step 614) and providing the oxygen species (step 616) can be performed in any suitable order. In various examples, the first oxide precursor 160 can be provided to reaction chamber 4 and may be repeatedly pulsed and/or purged for a number of cycles in a range of 1 to 100 and/or the oxygen species 166 can be provided to the reaction chamber and may be repeatedly pulsed and/or purged for a number of cycles in a range of 1 to 100.

In various examples, the first oxide precursor 160 can be provided to the reaction chamber before the oxygen species 166. In other examples, the oxygen species 166 can be provided to the reaction chamber before the first oxide precursor 160.

The step of providing the first oxide precursor 160 (step 614) and/or the step of providing an oxygen species (step 616) can be repeated any suitable number of times before a subsequent step takes place. For example, providing the first oxide precursor 160 (step 614) can be repeated multiple times before or after providing an oxygen species (step 616) to the reaction chamber, and/or providing an oxygen species (step 616) can be repeated multiple times before or after providing the first oxide precursor 160 (step 614).

In various examples, the steps of providing the first oxide precursor 160 and providing the oxygen species can be separated by a purge gas 164. Thus, after providing first oxide precursor 160 (step 614) to reaction chamber 4, a purge gas 164 can be provided (step 612) to reaction chamber 4. In examples in which oxygen species 166 is provided to reaction chamber 4 before first oxide precursor 160, the purge gas 164 can be provided (step 612) to the reaction chamber 4 after providing the oxygen species (step 616).

In various examples, a purge gas 164 can be provided (step 612) after each step (e.g., after providing the first oxide precursor 160 and providing the oxygen species 166, regardless of the order) and/or after deposition of the first oxide layer 540 or after a first oxide deposition cycle (i.e., a post-deposition purge step).

Steps 614 and 616, and any other steps involved in forming a the first oxide layer 540 (including purge steps) (collectively, a “oxide deposition cycle”) can be repeated any suitable number of times to achieve a desired thickness (Tfx) 541 of the first oxide layer 540 on substrate 530. For example, an oxide deposition cycle can be repeated until the first oxide layer is between 0.5 and 30 angstroms thick, or about 10 angstroms thick, or about 15 angstroms thick, or about 20 angstroms thick, or about 25 angstroms thick, or about 30 angstroms thick (“about” in this context means plus or minus two angstroms). Other thicknesses are possible and claimed subject matter is not limited in this regard.

In an example, method 600 may proceed to step 606 where a second oxide layer 550 may be formed on first oxide layer 540.

In various examples, forming second oxide layer 550 may comprise providing a second oxide precursor 162 (step 618) to a reaction chamber (e.g., reaction chamber 4 in FIG. 1A) where the second oxide precursor 162 may contact top surface 534 of substrate 530. Providing the second oxide precursor 162 can comprise providing the second oxide precursor 162 through a showerhead (e.g., showerhead 8), or through a crossflow fluid distribution system. In an example, second oxide layer 550 may comprise a second metal oxide.

In an example, the second oxide layer 550 may comprise lanthanum oxide (La₂O₃). In various examples, the second oxide precursor 162 may comprise any suitable lanthanum compound, such as tris(N,N′-di-i-propylformamidinato)lanthanum (La-FMD), tris(isopropylcyclopentadienyl)lanthanum (La(iPrCp)₃), tris(cyclopentadienyl) lanthanum (La(Cp)₃), tris(N,N′-diisopropylacetamidinate)lanthanum (La(iPr-MeAMD)₃), (La(thd)₃)-DMEA (thd=2,2,6,6-tetramethyl-3,5-heptanedione, DMEA=N,N′-dimethylethylenediamine), or the like or combinations thereof.

In another example, the second oxide layer 550 may comprise aluminum oxide (Al₂O₃). In various examples, the second oxide precursor 162 may comprise any suitable aluminum compound, such as, dimethylaluminum isopropoxide (DMAI) (CH₃)₂AlOCH(CH₃)₂, triethylaluminum (TEA), dimethylaluminum chloride (DMAC), or trimethylaluminum (TMA) or the like, or combinations thereof.

The second oxide precursor 162 may be supplied to chamber 4 via a second reactant source 12. The second oxide precursor 162 can be pulsed into the reaction chamber 4 for any suitable duration (e.g., for pulse times in the range of about 0.05 to 30 seconds). The pressure within the reaction chamber 4 during provision of the second oxide precursor 162 can be any suitable pressure, such as between 0.1 and 10 Torr.

In various examples, forming the second oxide layer 550 may further comprise providing an oxygen species 166 (step 620) to the reaction chamber. The oxygen species can be provided via oxygen source 15 through showerhead 8 to substrate 530, or through a crossflow fluid distribution system. The oxygen species 166 can be pulsed into the reaction chamber for any suitable duration (e.g., for pulse times of between 0.05 to 30 seconds). In various examples, an oxygen species 166 can be continuously provided to the reaction chamber. The pressure within the reaction chamber during provision of the oxygen species can be any suitable pressure, such as between 0.1 and 10 Torr.

The temperature during the steps to form the second oxide layer 550 can be between 100° C. and 300° C., or about 125° C., or about 175° C., or about 225° C., or about 275° C. (“about” in this context means plus or minus 50° C.). Other temperatures or temperature ranges are possible and claimed subject matter is not limited in this regard.

In an example, a first metal oxide layer (e.g., first oxide layer 540) can be deposited directly on a surface 532 of the substrate 530 and the second metal oxide layer (e.g., second oxide layer 550) may be deposited directly on a top surface 534 of the first metal oxide layer (e.g., first oxide layer 540), wherein the first metal oxide layer (e.g., first oxide layer 540) is thicker than the second metal oxide layer (e.g., second oxide layer 550).

The steps of providing the second oxide precursor 162 (step 618) and providing the oxygen species 166 (step 620) can be performed in any suitable order. In various examples, the second oxide precursor 162 can be provided to the reaction chamber and may be repeatedly pulsed and/or purged for a number of cycles in a range of 1 to 100 and/or the oxygen species 166 can be provided to the reaction chamber and may be repeatedly pulsed and/or purged for a number of cycles in a range of 1 to 100. Other pulse/purge cycles are contemplated and claimed subject matter is not limited in this regard.

In various examples, the second oxide precursor 162 can be provided to the reaction chamber before the oxygen species. In other examples, the oxygen species can be provided to the reaction chamber before the second oxide precursor 162.

The step of providing the second oxide precursor 162 (step 618) and/or the step of providing oxygen species 166 (step 620) can be repeated any suitable number of times before a subsequent step takes place. For example, providing the second oxide precursor 162 (step 618) can be repeated multiple times before or after providing an oxygen species 166 (step 620) to the reaction chamber 4, and/or providing an oxygen species 166 (step 620) can be repeated multiple times before or after providing the second oxide precursor 162 (step 618).

In various examples, the steps of providing the second oxide precursor 162 and providing the oxygen species 166 can be separated by a purge gas 164. Thus, after providing the second oxide precursor 162 (step 618) to the reaction chamber, a purge gas 164 can be provided (step 612) to the reaction chamber. In examples in which the oxygen species 166 is provided to the reaction chamber 4 before the second oxide precursor 162, the purge gas 164 can be provided (step 612) to the reaction chamber after providing the oxygen species 166 (step 620).

In various examples, a purge gas 164 can be provided (step 612) after each step (e.g., after providing the second oxide precursor 162 and providing the oxygen species 166, regardless of the order) and/or after deposition of the second oxide layer 550 or after a second oxide deposition cycle (i.e., a post-deposition purge step).

Steps 618 and 620, and any other steps involved in forming the second oxide layer 550 (including purge steps) (collectively, a “oxide deposition cycle”) can be repeated any suitable number of times to achieve a desired thickness (Tsx) 551 of the second oxide layer 550 on substrate 530. For example, an oxide deposition cycle can be repeated until the second oxide layer is between 0.5 and 30 angstroms thick, or about 10 angstroms thick, or about 15 angstroms thick, or about 20 angstroms thick, or about 25 angstroms thick, or about 30 angstroms thick (“about” in this context means plus or minus two angstroms). Other thicknesses are possible and claimed subject matter is not limited in this regard. In an example, thickness (Tsx) 551 may be equal to thickness (Tfx) 541. In another example, (Tsx) 551 may be greater than thickness (Tfx) 541. In another example, (Tsx) 551 may be less than thickness (Tfx) 541.

In various examples, the steps of providing the first precursor 160 and providing the second oxide precursor 162 can be separated by pulsing a purge gas 164 into chamber 4. Thus, after providing the first precursor 160 (step 614) and the oxygen species 166 (step 616) to the reaction chamber, a purge gas 164 can be provided (step 612) to reaction chamber 4. In examples in which the second oxide precursor 162 is provided to reaction chamber 4 before the first precursor 160, purge gas 164 can be provided to reaction chamber 4 after forming the second oxide layer 550 (step 606). In various examples, a purge gas 164 can be provided (step 612) after each step (e.g., after providing first oxide precursor 160, oxygen species 166, and/or second oxide precursor 162, regardless of the order).

In various examples, method 600 may proceed to step 608 where substrate 530 may be exposed to an excited species 151 (see FIG. 1B) to treat surface 536 of layer 550. Step 608 may be carried out in a different reaction chamber than steps 604 and 606. In various examples, substrate 530 may be transported from first reaction chamber 4 to second reaction chamber 102. During step 608, substrate 530 may be supported on a susceptor 114.

In an example, at step 622 excited species 151 may be generated in RPU 116 and transported to reaction chamber 102 where excited species 151 may contact substrate 530 surface 536. Excited species 151 may comprise hydrogen (H₂), nitrogen (N₂), or argon (Ar), or the like or combinations thereof. H₂, N₂, or Ar may be excited in RPU 116 alone or in a predetermined ratio. In an example, an H₂/N₂ ratio may be in the range of about 0 to 2, or about 0.25, or about 1.25 or about 1.75 or in the range of about 2 to 5, or about 2.5, or about 3, or about 3.5, or about 4 (“about” in this context means plus or minus 1). Other ranges are possible and claimed subject matter is not limited in this regard.

In an example, RPU 116 may generate excited species 151 over a variety of time periods, such as, in a range of about 10-500 seconds. Other ranges are possible and claimed subject matter is not limited in this regard.

During exposure to excited species 151, substrate 530 may be heated to about 100° C.-300° C., or about 150° C., or about 200° C., or about 250° C. or in the range of 250° C.-400° C., or about 275° C., or about 325° C., or about 375° C. or in the range of 300° C.-500° C., or about 360° C., or about 400° C., or about 450° C. (“about” in this context means plus or minus 50° C.). Other temperatures or temperature ranges are possible and claimed subject matter is not limited in this regard.

In an example, substrate 530 may be heated by susceptor 114 to modify the temperature. Susceptor 114 may be heated to a temperature in the range of 100° C.-300° C., or about 150° C., or about 200° C., or about 250° C. or in the range of 250° C.-400° C., or about 275° C., or about 325° C., or about 360° C. or in the range of 300° C.-500° C., or about 350° C., or about 400° C., or about 450° C. (“about” in this context means plus or minus 50° C.). Other temperatures or temperature ranges are possible and claimed subject matter is not limited in this regard.

In an example, subsequent to exposure to the excited species 151, a transition metal layer 560 may be formed on treated surface 536 of substrate 530. Substrate 530 may be transported to a different reaction chamber than was used to deposit the first oxide layer 540, second oxide layer 550 and/or to provide the excited species 151. For example, substrate 530 may be transported to reaction chamber 154 (see FIG. 1C) for additional processing. Alternatively, substrate 530 may be transported back to reaction chamber 4 or remain within reaction chamber 102 if equipped to perform both material deposition processing and plasma treatment. Claimed subject matter is not limited in this regard.

Continuing with an example wherein substrate 530 is transported to reaction chamber 154, method 600 may proceed to step 610 where a transition metal layer 560 is formed on treated surface 536. At step 624, a first transition metal layer precursor (e.g., transition metal layer precursor 174 in FIG. 1C) may be provided from chemical delivery vessel 40 to reaction chamber 154 via chemical delivery line 36.

First transition metal layer precursor 174 may be pulsed into the reaction chamber 154 for any suitable duration (e.g., pulse times of between 0.05 to 30 seconds). The number of pulses of the first transition metal layer precursors 174 may be determined based on a variety of factors including desired thickness of transition metal layer, flow rate, etc. In an example, pulses of first transition metal layer precursors 174 can vary between 5 to 100. Pulse times can also influence total pulses to achieve a certain thickness. The number of pulses can vary depending on the other chamber conditions such as temperature and pressure.

The transition metal layer precursor 174 may be provided through a showerhead 158 to substrate 530, or through a crossflow fluid distribution system. In an example, transition metal layer 560 may comprise a transition metal nitride, such as tungsten nitride (WN), molybdenum nitride (MoN), or the like or a combination thereof.

In various examples, first transition metal layer precursor 174 may comprise a transition metal nitride precursor. Such a transition metal nitride precursor may comprise bis(tert-butylimino) bis(tert-butoxy) Mo, bis(tert-butylimido)bis(dimethylamido) Mo(C₁₂H₃₀MoN₄), bis(tert-butylimido)bis(dimethylamido) Mo, a metalorganic precursor (e.g., molybdenum hexacarbonyl (Mo(CO)₆), a halide Mo precursor (e.g., molybdenum pentachloride (Mo(Cl)₅), a N- and/or S-containing Mo metalorganic precursor (e.g., Mo(NtBu)₂(StBu)₂), Mo(NMe₂)₄, Mo(NEt₂)₄, MO₂(NMe₂)₆, Mo(tBuN)₂(NMe₂)₂, Mo(tBuN)₂(NEt₂)₂, Mo(NEtMe)₄, Mo(NtBu)₂(StBu)₂, Mo(NtBu)₂(iPr₂AMD)₂Mo(thd)₃, MoO₂(acac), MoO₂(thd)₂, MoO₂(iPr₂AMD)₂, bis(tert-butylimido)-bis-(dimethylamido)tungsten ((tBuN)₂(Me₂N)₂W), bis(tertbutylimido)-bis(tert-butylamido)tungsten ((tBuN)₂W—(NHtBu)₂), or the like or combinations thereof.

In an example, transition metal layer 560 can be formed on treated surface 536 by contacting top surface 536 with first transition metal layer precursor 174. Alternatively, forming transition metal layer 560 includes contacting top surface 536 with a second transition metal layer precursor 174.

At step 625, a second transition metal layer precursor 175 may be pulsed into the reaction chamber 154 for any suitable duration (e.g., for pulse times of between 0.05 to 30 seconds).

The number of pulses of second transition metal layer precursors 175 may be determined based on a variety of factors including desired thickness of transition metal layer, flow rate, etc. In an example, pulses of second transition metal layer precursors 175 can vary between 5 to 100. Pulse times can also influence total pulses required to achieve a certain thickness. A number of pulses can vary depending on the other chamber conditions such as temperature and pressure.

Second transition metal layer precursor 175 may comprise a nitrogen source, for example, ammonia (NH₃), dimethyl hydrazine ((CH₃)₂NNH₂), or the like or combinations thereof. Second transition metal layer precursor 175 may be pulsed into the reaction chamber 154 for any suitable duration (e.g., for pulse times of between 0.05 to 30 seconds).

The number of pulses of second transition metal layer precursor 175 may be determined based on a variety of factors including desired thickness of transition metal layer 560, flow rate, etc.

Pulses of transition metal layer precursors 174 and 175 may be separated by providing a purge gas (e.g., purge gas 164) to reaction chamber 154 from purge gas source vessel 43 via chemical delivery line 38. The purge gas may remove excess precursor, byproducts, or other unwanted materials from chamber 154 which may be expelled by vacuum pump 180 to an exhaust system. The steps of providing the first transition metal layer precursor 174 (step 624) and providing the second transition metal layer precursor 175 (step 625) can be performed in any suitable order. In various examples, the first transition metal layer precursor 175 can be provided to the reaction chamber 154 and may be repeatedly pulsed and purged for a number of cycles in a range of 1 to 100 and/or the second transition metal layer precursor 175 can be provided to the reaction chamber and may be repeatedly pulsed and purged for a number of cycles in a range of 1 to 100. Other pulse cycles are contemplated and claimed subject matter is not limited in this regard.

In various examples, the first transition metal layer precursor 174 can be provided to the reaction chamber 154 before the second transition metal layer precursor 175. In other examples, the second transition metal layer precursor 175 can be provided to the reaction chamber before the first transition metal layer precursor 174.

The step of providing the first transition metal layer precursor 174 (step 624) and/or the step of providing second transition metal layer precursor 175 (step 625) can be repeated any suitable number of times before a subsequent step takes place.

In various examples, the steps of providing the first transition metal layer precursor 174 and providing the second transition metal layer precursor 175 (step 625) can be separated by a purge gas 164. Thus, after providing the first transition metal layer precursor 174 (step 624) to the reaction chamber 154, a purge gas 164 can be provided (step 612) to the reaction chamber 154. In examples in which the second transition metal layer precursor 175 is provided to the reaction chamber 154 before the first transition metal layer precursor 174, the purge gas 164 can be provided (step 612) to the reaction chamber 154 after providing second transition metal layer precursor 175 (step 625).

In various examples, a purge gas 164 can be provided (step 612) after each of steps 624 or 625.

The pressure within the reaction chamber 154 during provision of the transition metal layer precursors 174 and/or 175 can be any suitable pressure, such as between. 1 and 10 Torr. The temperature during the steps to form transition metal layer 560 can be between 150° C. and 500° C., or about 250° C., or about 350° C., or about 450° C. (“about” in this context means plus or minus 50° C.). Other temperatures or temperature ranges are possible and claimed subject matter is not limited in this regard.

In an example, transition metal layer 560 may be any suitable thickness. For example, transition metal layer 560 may have a thickness (T) 561 in the range of about 2.0 angstroms to about 150.0 angstroms. For example, a transition metal layer deposition cycle can be repeated until transition metal layer 560 is between 2.0 and 150.0 angstroms thick, or about 10 angstroms thick, or about 20 angstroms thick, or about 30 angstroms thick, or about 40 angstroms thick, or about 50 angstroms thick, 60 angstroms thick, or about 70 angstroms thick, or about 80 angstroms thick, or about 90 angstroms thick, or about 100 angstroms thick, 110 angstroms thick, or about 120 angstroms thick, or about 130 angstroms thick, or about 140 angstroms thick, or about 150 angstroms thick (“about” in this context means plus or minus 5 angstroms). Other thicknesses are possible and claimed subject matter is not limited in this regard.

After a desired thickness of transition metal layer 560 is reached, device structure 500 may proceed to further processing. For example, layer 560 may function as an etch stop layer in material processing applications for next-generation transistor architectures and/or fabrication of threshold voltage tuning layers. However, unless otherwise noted, the presently described methods are not limited to such applications.

In various examples, a substrate can remain in a single reaction chamber for one or more process steps discussed herein, or a substrate can be moved between reaction chambers for different process steps. For example, a substrate can remain in a single reaction chamber for oxide deposition cycles (e.g., steps 604, 606, and any purge steps). As another example, the substrate can remain in a single reaction chamber for first and second oxide layer deposition and surface treatment by an excited species.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A semiconductor processing method comprising:
a. supporting a substrate comprising one or more oxide layers disposed on the substrate on a substrate support in a first reaction chamber;
b. contacting a top surface of the one or more oxide layers of the substrate with an excited species;
c. supporting the substrate in a second reaction chamber; and
d. depositing a transition metal layer over the top surface subsequent to contacting the top surface with the excited species.

2. The semiconductor processing method of claim 1, further comprising depositing the one or more oxide layers on a surface of the substrate.

3. The semiconductor processing method of claim 1, wherein the depositing the transition metal layer comprises exposing the substrate to one or more transition metal layer precursors.

4. The semiconductor processing method of claim 3, wherein the transition metal layer is a transition metal nitride.

5. The semiconductor processing method of claim 4, wherein the transition metal nitride is molybdenum nitride (MoN) or tungsten nitride (WN).

6. The semiconductor processing method of claim 5, wherein the one or more transition metal layer precursors are selected from a group comprising: bis(tert-butylimino) bis(tert-butoxy) Mo, bis(tert-butylimido)bis(dimethylamido) Mo, bis(tert-butylimido)bis(dimethylamido) Mo, molybdenum hexacarbonyl, molybdenum pentachloride, Mo(NtBu)₂(StBu)₂, Mo(NMe₂)₄, Mo(NEt₂)₄, MO₂(NMe₂)₆, Mo(tBuN)₂(NMe₂)₂, Mo(tBuN)₂(NEt₂)₂, Mo(NEtMe)₄, Mo(NtBu)₂(StBu)₂, Mo(NtBu)₂(iPr₂AMD)₂Mo(thd)₃, MoO₂(acac), MoO₂(thd)₂, MoO₂(iPr₂AMD)₂, bis(tert-butylimido)-bis-(dimethylamido)tungsten, bis(tertbutylimido)-bis(tert-butylamido)tungsten, or a combination thereof.

7. The semiconductor processing method of claim 2, wherein the depositing the one or more oxide layers on the surface of the substrate comprises:
a. contacting the substrate with a first precursor to deposit a first oxide layer comprising a first metal oxide; and
b. contacting the substrate with a second precursor to deposit a second oxide layer comprising a second metal oxide.

8. The semiconductor processing method of claim 7, wherein the first metal oxide is different from the second metal oxide.

9. The semiconductor processing method of claim 8, wherein the first metal oxide is deposited directly on the surface of the substrate to form a first metal oxide layer and the second metal oxide is deposited directly on a top surface of the first metal oxide layer to form a second metal oxide layer, wherein the first metal oxide layer is thicker than the second metal oxide layer.

10. The semiconductor processing method of claim 9, wherein the first metal oxide layer is about 15 angstroms thick and the second metal oxide layer is about 10 angstroms thick.

11. The semiconductor processing method of claim 10, wherein the first metal oxide layer comprises hafnium oxide (HfO₂) and the second metal oxide layer comprises lanthanum oxide (La₂O₃) or aluminum oxide (Al₂O₃), or a combination thereof.

12. The semiconductor processing method of claim 1, wherein the excited species is generated in a remote plasma unit (RPU).

13. The semiconductor processing method of claim 12, wherein the excited species are radicals of argon (Ar), hydrogen (H₂), or nitrogen (N₂), or a combination thereof.

14. The semiconductor processing method of claim 13, wherein H₂ and N₂ are combined in a predetermined ratio.

15. The semiconductor processing method of claim 13, wherein the excited species is H₂.

16. The semiconductor processing method of claim 13, wherein contacting the top surface of the one or more oxide layers of the substrate further comprises heating the substrate support to adjust a temperature of the substrate.

17. The semiconductor processing method of claim 16, wherein the substrate support is heated to about 360° C.

18. The semiconductor processing method of claim 2, wherein the depositing the one or more oxide layers on the substrate and the contacting the top surface of the one or more oxide layers of the substrate with the excited species are performed in a same reaction chamber.

19. The semiconductor processing method of claim 2, wherein the depositing the one or more oxide layers on the substrate, the contacting the top surface of the one or more oxide layers of the substrate with the excited species and the depositing the transition metal layer over the substrate surface are performed in a same reaction chamber.

20. The semiconductor processing method of claim 2, wherein the depositing the one or more oxide layers on the substrate, the contacting the top surface of the one or more oxide layers of the substrate with the excited species and the depositing the transition metal layer over the substrate surface are performed in two or more reaction chambers.

21. The semiconductor processing method of claim 1, wherein the first reaction chamber and the second reaction chamber are a same chamber.
